(19) United States
(12) Patent Application Publication
(10) Pub. No.: US 2020/0148534 A1
(43) Pub. Date: May 14, 2020

(54) METHOD FOR ACHIEVING STICTION-FREE HIGH-ASPECT-RATIO MICROSTRUCTURES AFTER WET CHEMICAL PROCESSING

(71) Applicant: TEL FSI, Inc., Chaska, MN (US)

(72) Inventors: Brent D. Schwab, Chaska, MN (US); Christina A. Rathman, Chaska, MN (US); Steven L. Nelson, Chaska, MN (US)

(21) Appl. No.: 16/678,667

(22) Filed: Nov. 8, 2019

Related U.S. Application Data
(60) Provisional application No. 62/767,049, filed on Nov. 14, 2018.

(51) Int. Cl. B81C 1/00; B08B 3/08

(52) U.S. Cl. CPC B81C 1/00928; B81C 2201/0132; B08B 3/08; B81C 1/00849

(57) ABSTRACT

A method for wet chemical processing of high-aspect-ratio microstructures and exiting the wet chemical processing while avoiding stiction between the high-aspect-ratio microstructures is provided. The method includes providing a substrate containing etched microstructures, removing etch residue from the substrate using wet chemical processing, rinsing the substrate with an aqueous hydrogen fluoride solution after the wet chemical processing, and drying the substrate using an inert gas.

### CROSS-REFERENCE TO RELATED APPLICATIONS

This application is related to and claims priority to U.S. Provisional Patent Application Ser. No. 62/767,049, filed on Nov. 14, 2018, the entire contents of which are herein incorporated by reference.

### FIELD OF THE INVENTION

The present invention relates to wet chemical processing of microstructures on a substrate, and more particularly to a method for preventing stiction of high-aspect-ratio microstructures after wet chemical processing.

### BACKGROUND OF THE INVENTION

Stiction or adhesion of adjacent high-aspect-ratio micro-structures is often encountered after wet chemical processing, where the surface tension of a liquid between the micro-structures causes surfaces to adhere together during drying of the wet solution. Separating the surfaces is often complicated due to the fragile nature of the micro-structures. Therefore, new methods are needed for preventing stiction of microstructures after wet chemical processing.

### SUMMARY OF THE INVENTION

Embodiments of the invention describe a method for wet chemical processing of high-aspect-ratio microstructures and exiting the wet chemical processing while avoiding stiction between the high-aspect-ratio microstructures. According to one embodiment, the method includes providing a substrate containing etched microstructures, removing etch residue from the etched microstructures using wet chemical processing, rinsing the substrate with an aqueous hydrogen fluoride solution after the wet chemical processing, and drying the substrate using an inert gas to remove any water from the microstructures.

According to one embodiment, the method includes providing a substrate containing etched silicon pillars disposed on the substrate, where the etched silicon pillars extend in a direction perpendicular to a surface of the substrate, and removing etch residue from the substrate using wet chemical processing, where the wet chemical processing includes exposing the substrate to an acidic aqueous solution containing a mixture of sulfuric acid (H₂SO₄) and hydrogen peroxide (H₂O₂) to remove the etch residue from the substrate. The method further includes rinsing the substrate with deionized (DI) water to remove the acidic aqueous solution from the substrate, exposing the substrate to a basic aqueous solution containing a mixture of ammonium hydroxide (NH₄OH) and hydrogen peroxide (H₂O₂) to clean and neutralize the substrate, rinsing the substrate with an aqueous hydrogen fluoride (HF_{aq}) solution to render surfaces of the etched silicon pillars hydrophobic, and drying the substrate using an inert gas to remove any water from the etched silicon pillars.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a process flow diagram of a substrate processing method according to an embodiment of the invention;

FIG. 2 schematically shows through a cross-sectional view a substrate containing a plurality of etched microstructures according to an embodiment of the invention; and

FIG. 3 schematically shows through a cross-sectional view a substrate containing a plurality of etched microstructures experiencing stiction between adjacent etched microstructures.

### DETAILED DESCRIPTION OF SEVERAL EMBODIMENTS

Wet chemical processing, including substrate cleaning, is one of the most common yet most critical processing steps in semiconductor manufacturing, since it can have a huge impact on the success of the subsequent process step. Embodiments of the invention describe a method for wet chemical processing of high-aspect-ratio microstructures and exiting the wet chemical processing while avoiding stiction between the high-aspect-ratio microstructures on the substrate. The method of embodiments of the present invention may be used to process multiple wafer-like objects simultaneously, as occurs with batches of wafers when being processed in a spray processing tool such as the MERCURY™ or ZETA™ spray processors commercially available from TEL FSI, Inc., Chaska, Minn., or the Magellan™ system, also commercially available from TEL FSI, Chaska, Minn. Embodiments of the present invention may also be used in single wafer processing applications where the wafers are either moving or fixed, or in batch applications where the wafers are substantially stationary. An example of a single wafer processing system is the FSI Orion™. Single Wafer Cleaning System commercially available from TEL FSI, Inc., Chaska, Minn. The configuration and use of a spray processing tool has been further described in U.S. Pat. Nos. 5,971,368; 6,235,641; 6,274,506; 6,648,307; and 7,422,031, said patents being incorporated herein by reference in their entireties.

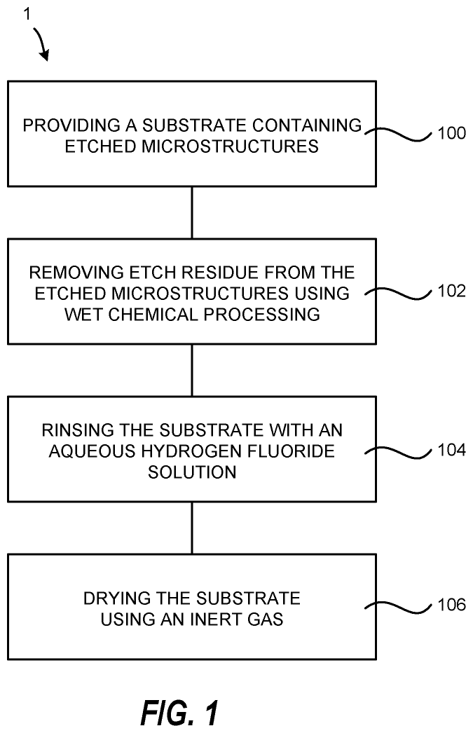

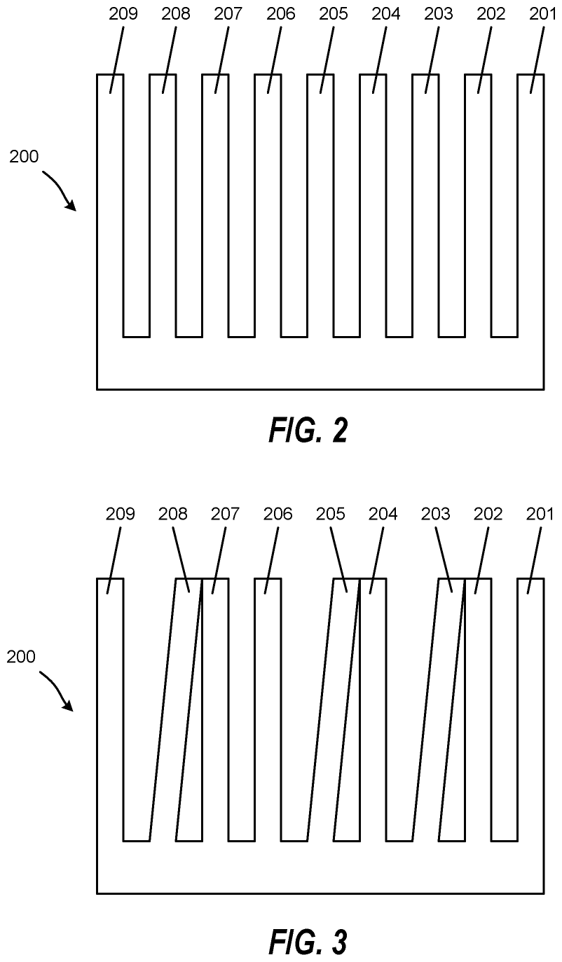

FIG. 1 is a process flow diagram for processing a substrate according to an embodiment of the invention. The process flow 1 includes, in step 100, providing a substrate containing etched microstructures. The substrate may be loaded into a batch spray processor, for example, the TEL FSI, Inc., ZETA™ Surface Cleaning System. In one example, the microstructures can comprise free-standing high-aspect-ratio Si or Si-containing pillars. In one example, the microstructures can comprise free-standing high-aspect-ratio Si pillars formed by deep etching of a Si substrate. This is schematically shown in FIG. 2 where the substrate 200 contains a plurality of high-aspect-ratio Si pillars 201-209 disposed on the substrate 200, and extending in a direction perpendicular to a surface of the substrate 200. In some examples, the Si pillars 201-209 can have an aspect-ratio (AR, height/width) greater than about 10, greater than about 20, greater than about 40, greater than about 50, or greater than about 60. The Si pillars are not limited to any particular shape and can, for example, have a square shape, a cylindrical shape, a triangular shape, or any other shape found in device applications.

The microstructures may be formed by dry anisotropic etching using well-known plasma processing. In one example, the plasma processing may include the Bosch process which is commonly used for deep Si etching technology and enables trench, hole and pillar fabrication for various device applications. The Bosch process is also known as deep-reactive-ion-etching (DRIE), and it is used for micro-electro-mechanical-systems (MEMS) device fabrication and through-silicon via (TSV) processing. The Bosch process includes alternating SF₆ plasma cycles and C₄F₈ plasma cycles. The SF₆ plasma cycles etch the Si, and the C₄F₈ plasma cycles create a sidewall protection layer.

The plasma processing that forms the microstructures commonly leaves etch residue on the microstructures that must be removed following the plasma processing to ensure proper operation and reliability of the final device. The etch residue can include an etch polymer, an organic contamination, or both an etch polymer and an organic contamination.

In 102, the method includes removing etch residue from the etched microstructures using wet chemical processing. The wet chemical processing can include one or more wet processing steps. According to one embodiment, the wet processing steps include 1) exposing the substrate to an acidic aqueous solution to remove the etch residue from the substrate; 2) rinsing the substrate with deionized (DI) water to remove remains of the acidic aqueous solution from the substrate; and 3) exposing the substrate to a basic aqueous solution to clean and neutralize any remaining etch residues. In some examples, a temperature of the acidic aqueous solution may be between about 60° C. and about 200° C., or between about 90° C. and about 150° C. The substrate may be exposed to the acidic aqueous solution for a time period between about 1 minute and about 20 minutes, or between about 3 minutes and about 10 minutes. In one example, the acidic aqueous solution can include a mixture of sulfuric acid (H₂SO₄) and hydrogen peroxide (H₂O₂), where the mixture can have a H₂SO₄:H₂O₂ ratio between about 1:1 and about 10:1, or between about 2:1 and about 4:1. In some examples, a temperature of the basic aqueous solution may be between about 20° C. and about 100° C., or between about 40° C. and about 70° C. The substrate may be exposed to the basic aqueous solution for a time period between about 1 minute and about 10 minutes, or between about 3 minutes and about 5 minutes. In one example, the basic aqueous solution can include a mixture of ammonium hydroxide (NH₄OH), hydrogen peroxide (H₂O₂), and water (H₂O), where the mixture can have a NH₄OH:H₂O₂:H₂O ratio between about 1:1:5 and about 1:1:500, or between 1:1:20 and about 1:1:100.

In one wet processing example, in step 1), a substrate containing microstructures in the form of Si pillars with an AR of approximately 60 was exposed to a mixture of H₂SO₄ and H₂O₂ at >95° C. for 2 minutes to remove etch residue from the Si pillars. Further, in step 2), the substrate was rinsed with the DI water at 60° C. for 6 minutes to remove remains of the aqueous acidic solution from the microstructures. Further, in step 3), the substrate was exposed to mixture of NH₄OH and H₂O₂ at 60° C. for 4 minutes to clean the substrate and neutralize any remaining etch residues from the exposure to the acidic aqueous solution in step 1).

In 104, the method thereafter includes rinsing the substrate with an aqueous hydrogen fluoride solution (HF_{aq}). In some examples, a temperature of the HF_{aq} may be around room temperature, or between about 20° C. and about 25° C. The substrate may be exposed to the HF_{aq} for a time period between about 1 minute and about 10 minutes, or between about 3 minutes and about 5 minutes. In one example, the HF_{aq} can have a HF:H₂O ratio between about 1:10 and about 1:500, or between about 1:20 and about 1:100. In one process example, the HF_{aq} was prepared by diluting a 49% HF_{aq} solution by 100:1 using DI water. The substrate was exposed to the HF_{aq} at 20° C. for 5 minutes for etching and removing any native or chemical silicon oxide formed on the substrate and making surfaces of the etched Si pillars hydrophobic. The exposure to the HF_{aq} results in surfaces of the etched Si pillars to be hydrogen terminated and hydrophobic.

In 106, the method includes drying the substrate using an inert gas such as N₂. The drying is performed to remove any remaining water from the etched microstructures before the substrate is removed from the process chamber. Any remaining water on the substrate can result in the microstructures re-oxidizing and sticking together, resulting in unwanted sticking of the microstructures 201-209 on the substrate 200 as schematically shown in FIG. 3.

The exposure to the HF_{aq} as the last step of the wet processing displaces the water between the microstructures from the previous step and makes the surfaces of the microstructures hydrophobic, thereby avoiding stiction of adjacent microstructures during and following subsequent drying with an inert gas. The use of exposure to the HF_{aq} as the last step of wet processing of high-aspect ratio microstructures is counterintuitive since the HF_{aq} exposure leaves HF-species on the high-aspect-ratio microstructures. However, the inventors have discovered that the exposure to the inert gas dries and evaporates the HF-species from the substrate and reduces or eliminates stiction of adjacent microstructures.

A method for wet chemical processing of high-aspect-ratio microstructures and exiting the wet chemical processing while avoiding stiction between the high-aspect-ratio microstructures has been disclosed in various embodiments. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A substrate processing method, comprising:
providing a substrate containing etched microstructures;
removing etch residue from the etched microstructures using wet chemical processing;
rinsing the substrate with an aqueous hydrogen fluoride solution after the wet chemical processing; and
drying the substrate using an inert gas to remove any water from the etched microstructures.

2. The method of claim 1, wherein the etched microstructures include semiconductor pillars disposed on the substrate, the semiconductor pillars extending in a direction perpendicular to a surface of the substrate.

3. The method of claim 2, wherein the semiconductor pillars contain or consist of silicon.

4. The method of claim 2, wherein the etched microstructures have an aspect ratio (height/width) greater than about 10.

5. The method of claim 2, wherein the etched microstructures have an aspect ratio (height/width) greater than about 50.

6. The method of claim 1, wherein the etch residue includes an etch polymer, an organic contamination, or both an etch polymer and an organic contamination.

7. The method of claim 1, wherein the wet chemical processing includes
exposing the substrate to an acidic aqueous solution;
rinsing the substrate with deionized (DI) water to remove the acidic aqueous solution from the substrate; and
exposing the substrate to a basic aqueous solution to clean and neutralize the substrate.

8. The method of claim 7, wherein the acidic aqueous solution contains a mixture of sulfuric acid (H₂SO₄) and hydrogen peroxide (H₂O₂).

9. The method of claim 7, wherein the basic aqueous solution contains a mixture of ammonium hydroxide (NH₄OH) and hydrogen peroxide (H₂O₂).

10. The method of claim 1 wherein the rinsing and drying prevents stiction of the microstructures.

11. A substrate processing method, comprising:
providing a substrate containing etched silicon pillars disposed on the substrate, where the etched silicon pillars extend in a direction perpendicular to a surface of the substrate, the etched silicon pillars containing etch residue thereon that includes an etch polymer, an organic contamination, or both an etch polymer and an organic contamination;
removing etch residue from the etched microstructure using wet chemical processing;
rinsing the substrate with an aqueous hydrogen fluoride solution after the wet chemical processing; and
drying the substrate using an inert gas to remove any water from the etched silicon pillars.

12. The method of claim 11, wherein the etched microstructures have an aspect ratio (height/width) greater than about 10.

13. The method of claim 11, wherein the wet chemical processing includes
exposing the substrate to an acidic aqueous solution;
rinsing the substrate with deionized (DI) water to remove the acidic aqueous solution from the substrate; and
exposing the substrate to a basic aqueous solution to clean and neutralize the substrate.

14. The method of claim 13, wherein the acidic aqueous solution contains a mixture of sulfuric acid (H₂SO₄) and hydrogen peroxide (H₂O₂).

15. The method of claim 13, wherein the basic aqueous solution contains a mixture of ammonium hydroxide (NH₄OH) and hydrogen peroxide (H₂O₂).

16. The method of claim 11, wherein the rinsing and drying prevents stiction of the microstructures.

17. A substrate processing method, comprising:
providing a substrate containing etched silicon pillars disposed on the substrate, where the etched silicon pillars extend in a direction perpendicular to a surface of the substrate;
removing etch residue from the substrate using wet chemical processing, wherein the wet chemical processing includes
exposing the substrate to an acidic aqueous solution containing a mixture of sulfuric acid (H₂SO₄) and hydrogen peroxide (H₂O₂) to remove etch residue from the substrate;
rinsing the substrate with deionized (DI) water to remove the acidic aqueous solution from the substrate;
exposing the substrate to a basic aqueous solution containing a mixture of ammonium hydroxide (NH₄OH) and hydrogen peroxide (H₂O₂) to clean and neutralize the substrate;
rinsing the substrate with an aqueous hydrogen fluoride solution to render surfaces of the silicon pillars hydrophobic; and
drying the substrate using an inert gas to remove any water from the etched silicon pillars.

18. The method of claim 17, wherein the rinsing and drying prevents stiction of the etched silicon pillars.

19. The method of claim 17, wherein the etched silicon pillars have an aspect ratio (height/width) greater than about 10.

20. The method of claim 17, wherein the etch residue includes an etch polymer, an organic contamination, or both an etch polymer and an organic contamination.
